(19) United States
(12) Patent Application Publication
(10) Pub. No.: US 2025/0112164 A1
(43) Pub. Date: Apr. 3, 2025

(54) CONTROLLING SUBSTRATE BUMP HEIGHT

(71) Applicant: Intel Corporation, Santa Clara, CA (US)

(72) Inventors: Bohan SHAN, Chandler, AZ (US); Onur OZKAN, Scottsdale, AZ (US); Ryan CARRAZZONE, Chandler, AZ (US); Rui ZHANG, Chandler, AZ (US); Haobo CHEN, Chandler, AZ (US); Ziyin LIN, Chandler, AZ (US); Yiqun BAI, Chandler, AZ (US); Kyle ARRINGTON, Gilbert, AZ (US); Jose WAIMIN, Gilbert, AZ (US); Hongxia FENG, Chandler, AZ (US); Srinivas Venkata Ramanuja PIETAMBARAM, Chandler, AZ (US); Gang DUAN, Chandler, AZ (US); Dingying David XU, Chandler, AZ (US); Bin MU, Tempe, AZ (US); Mohit GUPTA, Chandler, AZ (US); Jeremy D. ECTON, Gilbert, AZ (US); Brandon C. MARIN, Gilbert, AZ (US); Xiaoying GUO, Chandler, AZ (US); Steve S. CHO, Chandler, AZ (US); Ali LEHAF, Phoenix, AZ (US); Venkata Rajesh SARANAM, Phoenix, AZ (US); Shripad GOKHALE, Gilbert, AZ (US); Kartik SRINIVASAN, Gilbert, AZ (US); Edvin CETEGEN, Chandler, AZ (US); Mine KAYA, Scottsdale, AZ (US); Nicholas S. HAEHN, Scottsdale, AZ (US); Deniz TURAN, Chandler, AZ (US)

(21) Appl. No.: 18/374,932

(22) Filed: Sep. 29, 2023

(51) Int. Cl. H01L 23/538; H01L 21/48; H01L 23/00; H01L 25/065

(52) U.S. Cl. CPC H01L 23/5385; H01L 21/4846; H01L 24/13; H01L 24/16; H01L 25/0655; H01L 2224/13111; H01L 2224/13147; H01L 2224/1403; H01L 2224/16227

(57) ABSTRACT

A device comprises a substrate comprising a plurality of build-up layers and a cavity. A bridge die is located within the cavity and a plurality of cavity side bumps are on one side of the bridge die. A plurality of interconnect pads with variable heights are on one of the build-up layers of the substrate coupled to the plurality of the cavity side bumps to bond the bridge die to the substrate.

### BACKGROUND

Integrated circuit(s) and other electronic devices may be packaged in a semiconductor package. The semiconductor package may be integrated into an electronic system, such as a consumer electronic system. Today, high-performance CPUs and special application processors are more likely to be built with a disaggregated architecture using multiple chiplets in order to reduce die sizes which results in higher yields and lower costs. Embedded Multi-die Interconnect Bridge (EMIB) is a cost-effective approach to in-package high-density interconnect of heterogeneous chips. Instead of using a large silicon interposer typically found in other approaches, EMIB uses a very small bridge die, with multiple routing layers, that provide I/O and electrical interconnect paths between multiple dies. This bridge die is embedded as part of a substrate fabrication process and there can be many embedded bridges in a single substrate. The bridge die uses chip-side bumps to connect to a substrate, and bridge bumps to connect to another die the package in a first layer interconnect (FLI) during the die attach process.

The use of EMIBs will need to overcome technical problems that occur during both the cavity side bump connection with the substrate and the first layer interconnect connection.

### BRIEF DESCRIPTION OF THE DRAWINGS

FIG. 1A depicts a simplified cross-sectional schematic diagram illustrating a state-of-the-art semiconductor package having a bridge embedded in a cavity of the substrate.

FIGS. 1B and 1C illustrate that connecting the cavity side bumps to the interconnect pads of the substrate can create a risk of solder bump bridging (SBB).

FIG. 2A depicts a simplified cross-sectional schematic diagram illustrating a close-up view of the interface between the cavity side bumps of the bridge die and the interconnect pads on the substrate in accordance with one example embodiment of the disclosure.

FIG. 2B illustrates an example where the risk for SBB due to local undulation of the substrate can be minimized using variable height interconnect pads.

FIG. 2C illustrates an example of where the risk for SBB due to bridge die warpage can be minimized using variable height interconnect pads.

FIGS. 3A-3C illustrate an exemplary processing scheme for fabricating a semiconductor package having a plurality of variable height interconnect pads formed on a build-up layer of the substrate.

FIG. 4 depicts a simplified cross-sectional schematic diagram illustrating a close-up view of the interface between the bridge bumps and the bond pads in the solder resist layer in accordance with the further embodiment of the disclosure.

FIGS. 5A-5E illustrate an exemplary processing scheme for fabricating a semiconductor package with SROs having variable volumes and bond pads.

FIGS. 6A and 6B illustrate a wafer composed of semiconductor material and may include one or more dies having integrated circuit (IC) structures formed on the surface of the wafer.

FIG. 7 illustrates a block diagram of an electronic system, in accordance with an embodiment of the present disclosure.

FIG. 8 is a cross-sectional side view of an integrated circuit (IC) device assembly that may include a substrate with controlled bump height, in accordance with one or more of the embodiments disclosed herein.

FIG. 9 illustrates a computing device in accordance with one implementation of the disclosure.

### DESCRIPTION OF THE EMBODIMENTS

Methods and architectures for controlling substrate bump height in a semiconductor package are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments of the disclosure may provide a semiconductor device, which may include a semiconductor package and a method for fabrication of the device. In example embodiments, the device may have one or more bridge dies, such as one or more embedded dies within an embedded multi-die interconnect bridge (EMIB)-based semiconductor package, as described herein. The device with the embedded bridge die may be fabricated using the methods disclosed herein. The bridge die may be provided within a package substrate, such as in a cavity formed within the substrate, and the substrate includes variable height interconnect pads that connect cavity side bumps of the bridge die to the substrate. The bridge die may further include variable height bond pads connected to bridge bumps in a first layer interconnect. The variable height interconnect pads and bond pads enable relatively improved interconnections between electrical components (e.g., integrated circuits) provided on the semiconductor package.

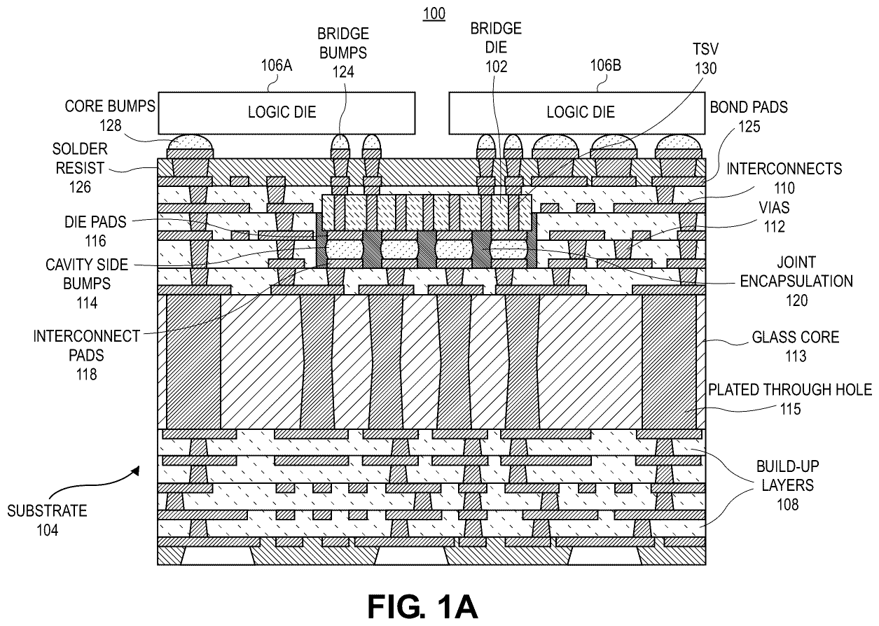

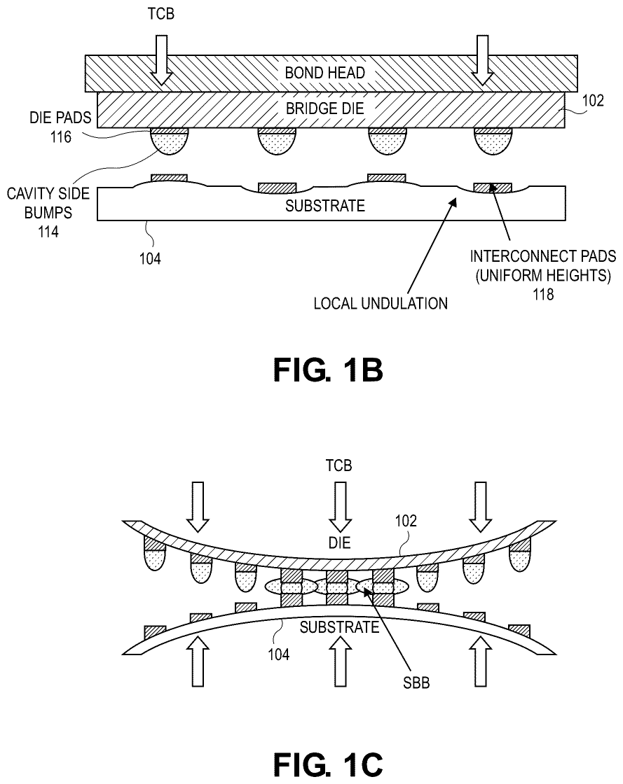

To provide context, FIG. 1A depicts a simplified cross-sectional schematic diagram illustrating a state-of-the-art semiconductor package 100 having a bridge die 102 embedded in a cavity (not shown) of a substrate 104. The semiconductor package 100 further includes logic die 106A and logic die 106B (collectively referred to as logic dies 106) mounted to a surface of the substrate 104 and coupled to the bridge die. In one specific example, the bridge die 102 may comprise an embedded interconnection bridge (EMIB).

The substrate 104 may comprise a plurality of build-up layers 108, each comprising interconnects 110 and vias 112 encapsulated with a dielectric material. The interconnects 110 and vias 112 provide electrical pathways for signals between electronic components (e.g., integrated circuits, passive devices, etc.), input/output (I/O) connections on the semiconductor package, signal fan out from/to the electronic components, signal connections between two or more electrical components, power delivery to electrical component(s), ground connections to electrical component(s), clock signal delivery to the electrical component(s), combinations thereof, or the like. In one embodiment, the interconnects 110 and vias 112 may comprise a conductive material such as copper. The substrate 104 may further include a glass core 113 with plated through holes 115 connecting the build-up layers 108 located on each side of the glass core.

The bridge die 102 is a small silicon chip that provides dedicated ultra-high-density interconnects between one or more of the logic die. The bridge die 102 is coupled to the substrate 104 with cavity side bumps 114, which are coupled between die pads 116 on the bridge die 102 and interconnect pads 118 in one of the build-up layers 108 in substrate 104. In one embodiment, the interconnect pads 118 may comprise a conductive material such as plated copper or tin. A joint encapsulation material 120 may cover the cavity side bumps 114.

The bridge die 102 is connected to logic dies 106 through bridge bumps 124, large core bumps 128, and bond pads 125 on the substrate 104, which are formed in a solder resist (SR) layer 126. The interconnection between the bridge die 102 and the logic dies 106 through the bridge bumps 124 and bond pads 125 may be referred to as a first layer interconnect (FLI). In one embodiment, the bridge bumps 124 and the core bumps 128 may comprise a conductive material such as plated copper or tin.

The bridge die 102 further includes a plurality of through-silicon vias (TSVs) 130 connected between the cavity side bumps 114 and the bond pads 125. For high-frequency signals within the semiconductor package 100, the length of the die-to-die connections and the interconnects 110 and vias 112 is very important. In some embodiments, one semiconductor package architecture option is to embed the bridge die 102 in the substrate 104 directly beneath one of the logic dies 106 (i.e., in the die shadow). This allows the connected signals to be very short in length, which is equal to the combined height of the FLI and the bridge die 102.

The attachment of the cavity side bumps 114 to the interconnect pads 118 on the substrate 104, and the attachment of the bridge bumps 124 of the bridge die 102 to the logic dies 106 are both performed by a thermal compressive bonding process (TCB). Conventionally, both the interconnect pads 118 on the substrate 104 and bond pads 125 in the FLI are formed to respective uniform heights.

There are challenges when attempting to fabricate semiconductor package 100 that are related to the connection between the cavity side bumps 114 to interconnect pads 118 of the substrate 104, and the connection between bridge bumps 124 and the logic dies 106 through bond pads 125 in the FLI on top of the substrate.

FIGS. 1B and 1C illustrate that connecting the cavity side bumps 114 to the interconnect pads 118 of the substrate 104 can create a risk of solder bump bridging (SBB). FIG. 1B illustrates that due to local undulation of the substrate 104, the interconnect pads 118 formed thereon will be non-uniform in height. Consequently, attaching the cavity side bumps 114 of the bridge die 102 to the interconnect pads 118 through the thermal compressive bonding (TCB) process creates a risk for solder bump bridging (SBB). Solder bump bridging (SBB) is a type of semiconductor packaging defect in which two or more solder bumps are connected by a thin bridge of solder.

FIG. 1C illustrates die warpage during bridge die 102 to substrate 104 bonding (e.g., TCB process) when uniform height interconnect pads 118 are used, which may lead to SBB. If the bridge die 102 warpage is high at the center of the bridge die 102 and the interconnect pads 118 are of equal height, then the center cavity side bumps 114 may be pressed onto the center interconnect pads 118 causing SBB, while the outer cavity side bumps 114 may fail to touch the outer interconnect pads 118.

There are also challenges faced when connecting the bridge bumps 124 of the bridge die 102 to the logic dies 106 through the bond pads 125. As shown in FIG. 1A, the bridge die 102 has long plated through holes 115 under the footprint area of the bridge die 102. This will increase substrate crowning due to thermal expansion. Crowning in semiconductor packages is a phenomenon where a substrate (e.g. the bridge die) bends upwards in the center due to the difference in thermal expansion coefficients between the substrate and the other materials in the package, such as the logic die, the underfill, and the encapsulant. The substrate 104 may crown by approximately 2 um, also creating SBB risk during TCB of the logic dies 106.

Another challenge is that the core bumps 128 and the bridge bumps 124 are fabricated during an electroplating process in which nickel or tin is plated with copper. The problem is that for the bridge bumps 124 located in the die shadow of one of the logic dies 106, the process results in high plating edge effects causing height variations in the bridge bumps 124. That is, the bridge bumps 124 located under one of the logic die 106s nearer the edge boundary of the logic die 106 may have increased height compared to the bridge bumps 124 located nearer the center of the logic die 106. High plating effects also cause bridge bump thickness variation in which the thickness of the plated metal is greater for the bridge bumps 124 nearer the edges of the die shadow the logic die 106 than for the bridge bumps 124 nearer the center of the logic die 106. Bridge bump height and thickness variations make it challenging to reliably attach the logic dies 106 to the bridge bumps 124 and is a further SBB risk. SBB is a serious problem because it can lead to low bridge die bonding quality and low yield since SBB can lead to electrical shorts, which can cause the package to fail.

In accordance with one or more embodiments, a semiconductor package structure with an embedded bridge die is in a cavity formed within a substrate. The substrate includes variable height interconnect pads that connect cavity side bumps of the bridge die to the substrate. The bridge die may further include variable height bond pads in a first layer interconnect (FLI) on the top of the substrate. The variable height interconnect pads and bond pads enable improved interconnections between electrical components (e.g., integrated circuits) in the semiconductor package.

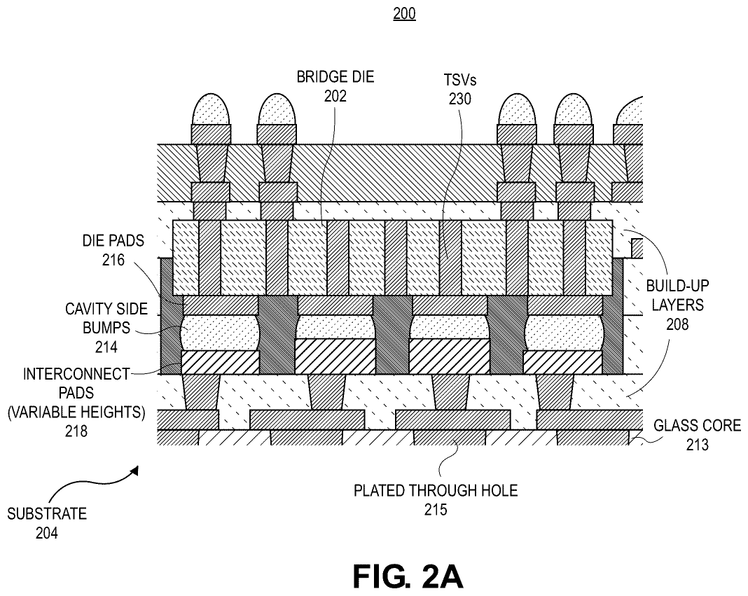

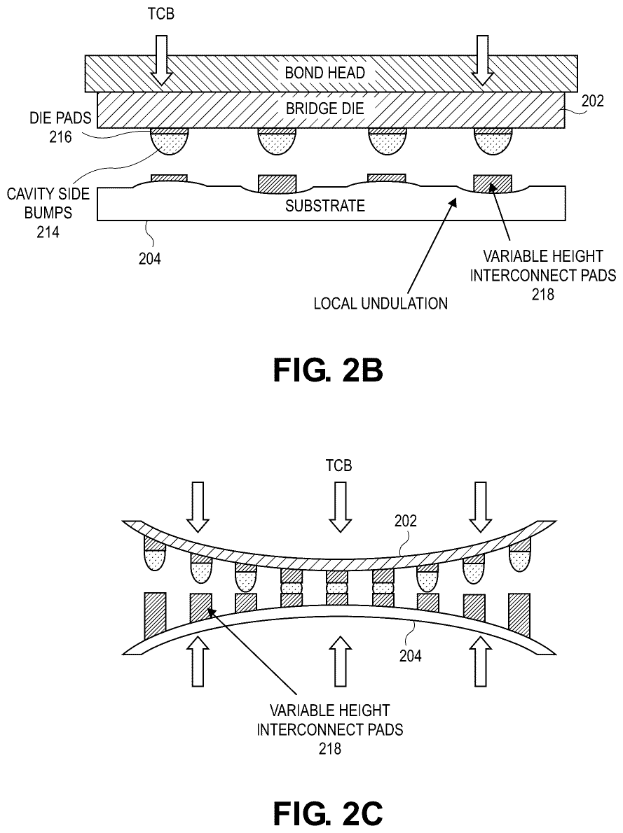

FIG. 2A depicts a simplified cross-sectional schematic diagram illustrating a close-up view of the interface between the cavity side bumps 214 of the bridge die 202 and the interconnect pads 218 on the substrate 204 in accordance with one example embodiment of the disclosure.

Similar to semiconductor package 100, semiconductor package 200 includes a substrate 204 comprising a plurality of build-up layers 208 and a cavity (not shown) formed within the substrate 204. A bridge die 202 is located in the cavity. A plurality of cavity side bumps 214 is formed on at least one side of the bridge die 202. The bridge die 202 further includes die pads 216 connect to the cavity side bumps 214 and TSVs 230. The substrate further includes a glass core 213 with plated through holes 215.

According to the disclosed embodiments, rather than use the conventional interconnect pads 118 (FIG. 1) that have uniform heights, a plurality of interconnect pads 218 that have variable heights are formed on one of the build-up layers 208 of the substrate 204 and are coupled to the plurality of cavity side bumps 214 to bond the bridge die 202 to the substrate 204 through die pads 216. In embodiments, interconnect pads 218 may range in height from +−25−50%.

FIG. 2B illustrates an example where the risk for SBB due to local undulation of the substrate 204 can be minimized using variable height interconnect pads 218. Depending on the actual undulation location in the substrate 204, one or more of a plurality of interconnect pads 218 can be formed with increased height compared to other ones of the interconnect pads 218 as needed in high-risk areas. The use of taller interconnect pads 218 helps combat substrate 204 undulations to avoid additional bonding force, which can cause SBB, or using not enough force, which can cause opens.

FIG. 2C illustrates an example of where the risk for SBB due to bridge die 202 warpage can be minimized using variable height interconnect pads 218. If the risk for SBB due to bridge die 202 warpage is highest at the center of the bridge die 202, then variable height interconnect pads 218 can be used. For example, the interconnect pads 218 having the shortest height can be aligned with cavity side bumps 214 near the center of the bridge die 202. The interconnect pads 218 can then gradually increase in height as the interconnect pads 218 near edges of the bridge die 202. Due to the adjusted interconnect pad heights, the bridge die 202 attach will have a higher bonding quality and overall yield.

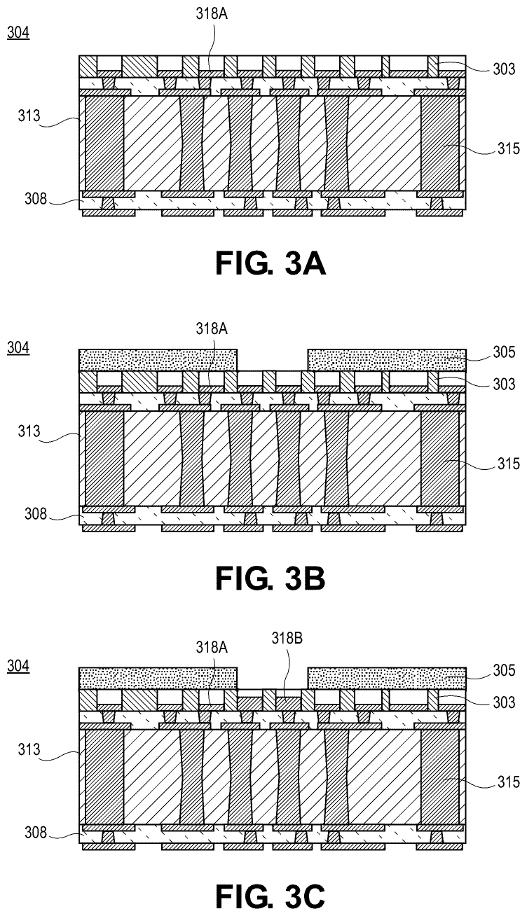

FIGS. 3A-3C illustrate an exemplary processing scheme for fabricating a semiconductor package having a plurality of variable height interconnect pads formed on a build-up layer of the substrate.

FIG. 3A shows that the process may begin once the substrate 304 is formed with build-up layers 308, glass core 313, and plated through holes 315, for example, by a suitable lithography patterning process. A first resist layer 303 is deposited on top of the substrate 304 and then patterned to create exposed areas. A conductive material is then deposited in the exposed areas of the first resist layer 303 to create a first set of interconnect pads 318A having a first height.

FIG. 3B shows a second resist layer 305 is deposited over the first resist layer 303 and patterned to expose the first set of interconnect pads 318A in high-risk areas for further plating. In one embodiment, this structure is formed using, for example, a double lithography patterning process (or a double lithography patterning/plating process). As used herein, the “double lithography pattering process” refers to a first photoresist deposited and patterned over a seed layer (i.e., a first litho-plate), and a second photoresist deposited and patterned over the first photoresist (i.e., a second litho-plate).

FIG. 3C shows that additional conductive material is deposited over the first set of interconnect pads 318A in the exposed areas of the second resist layer 305 to create a second set of interconnect pads 318B having a second height greater than the first height of the first set of interconnect pads 318A. Thus, this double lithography process enables variable height interconnect pads to mitigate die warpage and substrate undulation-induced issues.

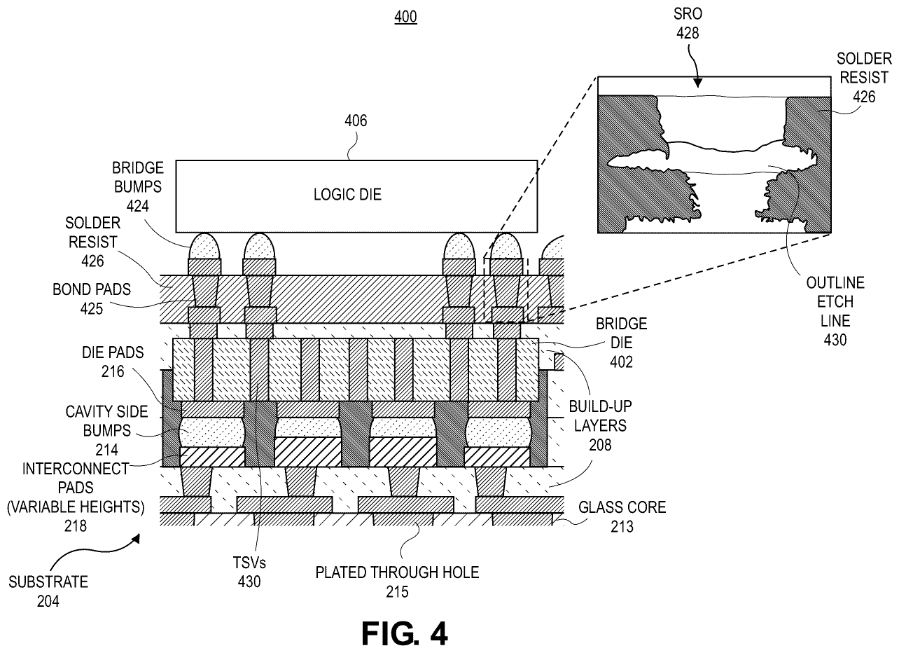

FIG. 4 depicts a simplified cross-sectional schematic diagram illustrating a close-up view of the interface between the bridge bumps 424 and the bond pads 425 in the solder resist layer 426 in accordance with the further embodiment of the disclosure.

Semiconductor package 400 includes a substrate 404 comprising a plurality of build-up layers 208 and a cavity formed within the substrate 404. The bridge die 402 is located in a cavity. A solder resist (SR) layer 426 comprising the first layer interconnect (FLI) is on one side of the substrate 204. A plurality of bridge bumps 424 is in the FLI. A logic die 406 bonds with the substrate 204 through the plurality of bridge bumps 424 (and optionally core bumps 128 (FIG. 1A). The bridge die 402 may further include die pads 216 connected to cavity side bumps 214. The substrate 204 may include a glass core 213 with plated through holes 215.

However, as described above, challenges to the logic die attach include possible crowning of the bridge die 402 in which the bridge die 402 bends upwards in the center due to the difference in thermal expansion coefficients due to the glass core 213 and plated through holes 215. The other challenge is that due to electroplating edge effects, conventional bridge bumps 124 (FIG. 1A) may include bridge both bridge bump height variation and thickness variation. For example, bridge bumps 124 located under one of the logic dies 106 nearer the edge boundary of the logic die may have increased height compared the bridge bumps 124 located nearer the center of the logic die. Both bridge die crowning and edge effects increase the risk of SBB.

According to the further embodiments, the risk of SBB due to crowning of the bridge die and/or edge effects are mitigated. This is accomplished by using a plurality of solder resist opens (SROs) 428 that have variable volumes. A conductive material fills the plurality of SROs 428 to create a plurality of bond pads 425. The SROs 428 are filled with a same volume of conductive material. A portion of the plurality of bond pads 425 has variable heights due to the SROs 428 having variable volumes. The plurality of bond pads 425 is connected to the plurality of bridge bumps 424.

The increased or decreased volumes of the SROs 428 can be achieved by variably increasing or decreasing the diameters of the SROs 428. In embodiments, a portion of the SROs 428 has variably increased or decreased volumes and a portion of the bond pads 425 has variably reduced or increased heights, respectively. As an example, the portion of the SROs 428 may have variably increased volumes and the portion of the bond pads 425 may have variably reduced heights. Both may be located in the region of the FLI where bridge die crowning is expected. The volumes of the SROs 428 may be increased or decreased either by: i) increasing or decreasing the diameter of the SROs 428 selectively, or ii) selectively drilling these SROs 428 and performing an outline etching so the depth of the SROs is increased or decreased.

In embodiments, the plurality SROs 428 with variable volumes are filled with the same volume of conductive material to create the bond pads 425 with variable heights. In embodiments, the heights of the bond pads 425 are directly proportional to the volume difference between the plurality of SROs 428.

In one embodiment, a portion of the plurality of SROs 428 has variably increased volumes compared to other SROs 428, while the diameters of the bond pads 425 remain uniform but with reduced heights.

The zoomed-in cross-section view of an SRO in FIG. 4 shows that due to the outline etch process, the SROs 428 having increased volumes due to variable diameters have a cross-section that includes an outline etch line 430 near a midsection of the SROs 428. Additionally, cross-section imaging of a plurality of SROs 428 will show visible diameter differences between various SROs 428 in the semiconductor package.

As an example, the heights of the bridge bumps 424 where bridge die crowning is expected can be reduced by increasing the SRO volume, either by increasing the SRO diameter selectively or by selectively drilling these SROs 428 and performing an outline etch. In addition, edge effects can completely be eliminated, resulting in a reduction in bridge bump thickness variation. BTV reduction enables EMIB technology, larger form factor products and/or further bump pitch scaling.

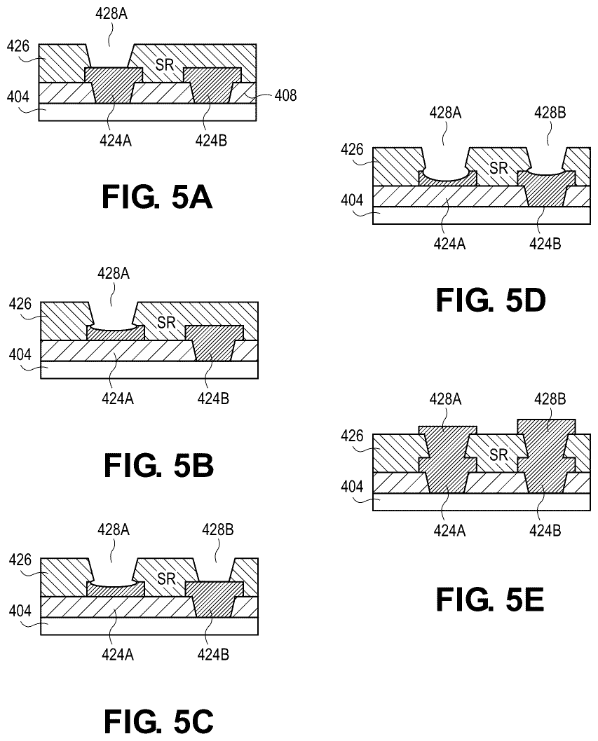

FIGS. 5A-5E illustrate an exemplary processing scheme for fabricating a semiconductor package having SROs with variable volumes and bond pads therein.

FIG. 5A shows that the process may begin after the substrate 404 is formed with build-up layers 408. At least one first bridge bump 424A and at least one second bridge bump 424B are formed with uniform heights on a surface of the substrate 404 using a suitable lithography patterning process. In embodiments, the first bridge bump is to be located under the logic die near a boundary of the logic die 406 and the second bridge die is to be located under the logic die nearer the center of the logic die. A solder resist layer 426 is deposited on the substrate 404 and then patterned to create a first solder resist open (SRO) 428A over the first bridge bump 424A.

FIG. 5B shows that a first outline etch is performed to remove a first portion of the solder resist 426 at a bottom of the first SRO 428A to a first diameter and a first volume.

FIG. 5C shows that solder resist layer 426 is patterned and etched to form a second SRO 428B over the second bridge bump 424B.

FIG. 5D shows that a second outline etch is performed to remove a portion of the solder resist 426 at a bottom of the second SRO 428B to a second diameter and a second volume that are less than the first diameter and the first volume. At this point the first bridge bump 424A located closer to the edge of the logic die 406 (FIG. 4) has a larger SRO critical dimension (CD) than the second bridge bump 424B closer to the center of the logic die 406.

FIG. 5E shows that conductive material is deposited over the first bridge bump 424A in the first SRO 428A to form the first bridge bump 424A to a first height above the solder resist layer 426. The conductive material is deposited over the second bridge bumps 424B and the second SRO 428B to form the second bridge bump 424B to a second height above the solder resist layer 426 that is greater than the first height. Consequently, the edge bridge bump 424A is plated to a lower height than the center bridge bump 424B due to the larger volume of SRO 428A.

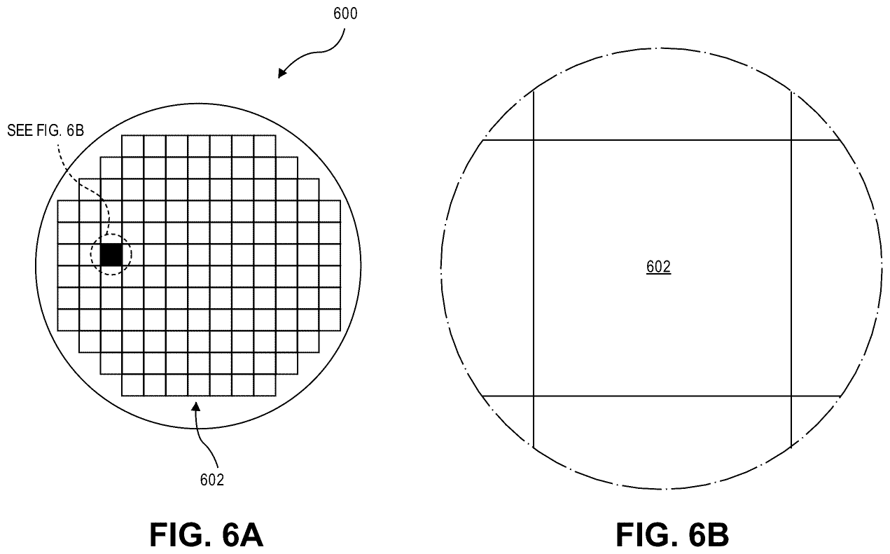

Referring to FIGS. 6A and 6B, a wafer 600 may be composed of semiconductor material and may include one or more dies 602 having integrated circuit (IC) structures formed on the surface of the wafer 600. Each of the dies 602 may be a repeating unit of a semiconductor product that includes any suitable IC (e.g., ICs including a substrate with controlled bump height, such as described above. After the fabrication of the semiconductor product is complete, the wafer 600 may undergo a singulation process in which each of the dies 602 is separated from one another to provide discrete “chips” of the semiconductor product. In particular, structures that include embedded non-volatile memory structures having a substrate with controlled bump height, as disclosed herein may take the form of the wafer 600 (e.g., not singulated) or the form of the die 602 (e.g., singulated). The die 602 may include one or more embedded non-volatile memory structures and/or supporting circuitry to route electrical signals, as well as any other IC components. In some embodiments, the wafer 600 or the die 602 may include an additional memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on the same die 602 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

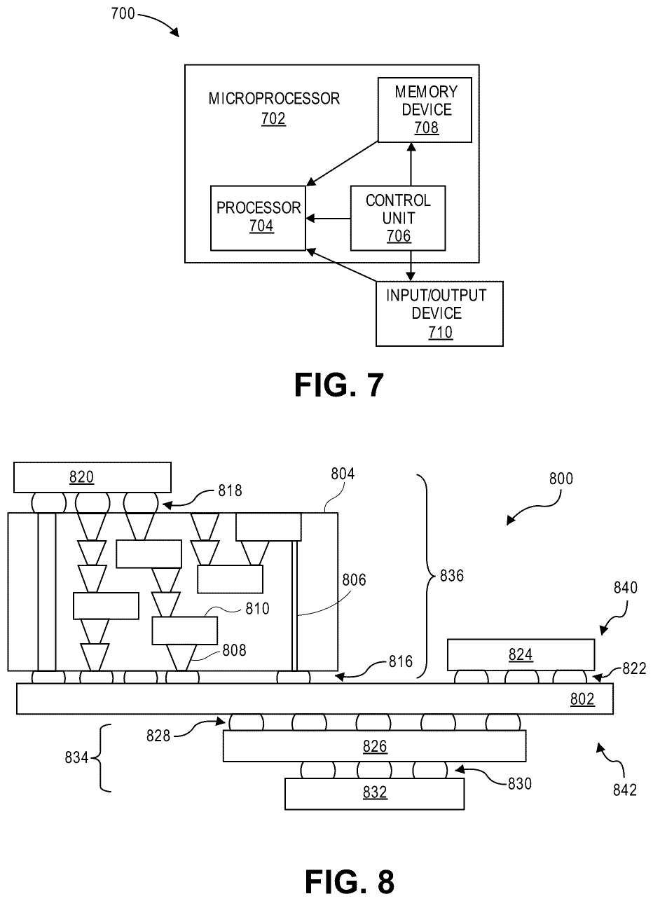

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations that are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a non-volatile memory cell as described in the present description. In an embodiment, the memory device 708 is embedded in the microprocessor 702, as depicted in FIG. 7. In an embodiment, the processor 704, or another component of electronic system 700, includes a substrate with controlled bump height, such as those described herein.

FIG. 8 is a cross-sectional side view of an integrated circuit (IC) device assembly that may include a substrate with controlled bump height, in accordance with one or more of the embodiments disclosed herein.

Referring to FIG. 8, an IC device assembly 800 includes components having one or more integrated circuit structures described herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802. Generally, components may be disposed on one or both faces 840 and 842. In particular, any suitable ones of the components of the IC device assembly 800 may include a number of a multilayer high-k gate dielectric, such as disclosed herein.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804. It is to be appreciated that additional interposers may be coupled to the interposer 804. The interposer 804 may provide an intervening substrate used to bridge the circuit board 802 and the IC package 820. The IC package 820 may be or include, for example, a die (the die 602 of FIG. 6B), or any other suitable component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804. In other embodiments, the IC package 820 and the circuit board 802 may be attached to the same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 810 and vias 808, including but not limited to through-silicon vias (TSVs) 806. The interposer 804 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

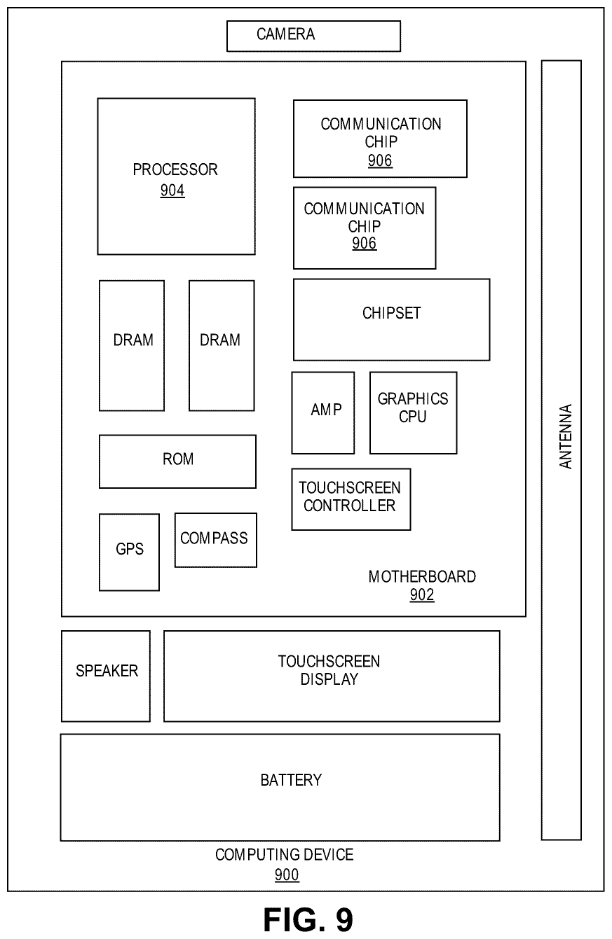

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter-range wireless communications such as Wi-Fi and Bluetooth and a second communication chip 906 may be dedicated to longer-range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor includes a substrate with controlled bump height, in accordance with implementations of embodiments of the disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the disclosure, the integrated circuit die of the communication chip 906 includes a substrate with controlled bump height, in accordance with implementations of embodiments of the disclosure.

In further implementations, another component housed within the computing device 900 may contain an integrated circuit die that includes a substrate with controlled bump height, in accordance with implementations of embodiments of the disclosure.

In various implementations, the computing device 900 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Thus, embodiments described herein include a direct die-two-die connection through an interposer without vias.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example embodiment 1: A device comprises a substrate comprising a plurality of build-up layers and a cavity. A bridge die is located within the cavity and a plurality of cavity side bumps are on one side of the bridge die. A plurality of interconnect pads with variable heights are on one of the build-up layers of the substrate coupled to the plurality of the cavity side bumps to bond the bridge die to the substrate.
Example embodiment 2: The device of embodiment 1, wherein the plurality of interconnect pads range in height from +−25−50%.
Example embodiment 3: The device of embodiment 1 or 2, wherein the plurality of interconnect pads comprise plated copper.
Example embodiment 4: The device of embodiment 1, 2, or 3, wherein the bridge die further includes a through-silicon via (TSV).
Example embodiment 5: The device of embodiment 1, 2, 3, or 4, further comprising a solder resist (SR) layer comprising a first layer interconnect (FLI) on one side of the substrate. A plurality of bridge bumps is in the FLI. A logic die is connected to the substrate through the plurality of bridge bumps.
Example embodiment 6: The device of embodiment 5, further comprises a plurality of solder resist opens (SROs) in the FLI, a portion of the plurality of SROs having variable volumes; and a conductive material filling the plurality of SROs to create a plurality of bond pads, the plurality of SROs filled with a same volume of conductive material, and a portion of the plurality of bond pads has variable heights due to the SROs having variable volumes, and the plurality of bond pads are connected to the plurality of bridge bumps.
Example embodiment 7: The device of embodiment 6, wherein the bridge dies further includes a through-silicon via (TSV) connected to the plurality of bridge bumps to connect the bridge die to the logic die.
Example embodiment 8: A method for fabricating a device comprises forming a substrate comprising a plurality of build-up layers. A first resist layer is deposited on top of the substrate and patterned the first resist layer to create exposed areas. A conductive material is deposited in the exposed areas of the first resist layer to create a first set of interconnect pads to a first height. A second resist layer is deposited over the first resist layer and patterned the second resist layer to expose the first set of interconnect pads. The conductive material is deposited over the first set of interconnect pads in the exposed areas of the second resist layer to create a second set of interconnect pads to a second height greater than the first height of the first set of interconnect pads.
Example embodiment 9: The method of embodiment 8 further comprising: forming the first set of interconnect pads and the second set of interconnect pads to a height from +−25−50% of each other.
Example embodiment 10: A device comprises a substrate comprising a plurality of build-up layers and a cavity. A bridge die is located within the cavity. A solder resist (SR) layer comprising a first layer interconnect (FLI) is on one side of the substrate. A plurality of bridge bumps is in the FLI. A logic die is connected to the substrate through the plurality of bridge bumps. A plurality of solder resist opens (SROs) is in the FLI, a portion of the plurality of SROs having variable volumes. A conductive material fills the plurality of SROs to create a plurality of bond pads, the plurality of SROs are filled with a same volume of conductive material, and a portion of the plurality of bond pads has variable heights due to the SROs having variable volumes, and the plurality of bond pads are connected to the plurality of bridge bumps.
Example embodiment 11: The device of embodiment 10 wherein the portion of the plurality of SROs having variable volumes has variable diameters.
Example embodiment 12: The device of embodiment 11 wherein the plurality of SROs has a cross-section with an outline etch line near a midsection of the SROs.
Example embodiment 13: The device of embodiment 10, 11, or 12, wherein the portion of the plurality of SROs has variably increased or decreased volumes, and the portion of the bond pads has variably reduced or increased heights, respectively.
Example embodiment 14: The device of embodiment 10, 11, 12, or 13 wherein a cross-section of the SROs having variable volumes and diameter differences.
Example embodiment 15: The device of embodiment 10, 11, 12, 13, or 14, wherein the bridge die further includes a through-silicon via (TSV) connected to the plurality of bridge bumps that connect the bridge die to the logic die.
Example embodiment 16: The device of embodiment 10, 11, 12, 13, 14, or 15 further comprising: a plurality of a plurality of cavity side bumps on one side of the bridge die
Example embodiment 17: The device of embodiment 16, further comprising: a plurality of interconnect pads with variable heights on one of the plurality of build-up layers of the substrate coupled to the plurality of the cavity side bumps to bond the bridge die to the substrate.
Example embodiment 18: The device of embodiment 17, wherein the interconnect pads range in height from +−25−50%.
Example embodiment 19: A method of fabricating a device, the method comprising: forming a substrate comprising a plurality of build-up layers; forming at least a first bridge bump and a second bridge bump with uniform heights on the substrate; depositing a solder resist layer on the substrate and patterning the resist layer to create a first solder resist open (SRO) over the first bridge bump; performing a first outline etch to remove a first portion of the solder resist layer around a diameter of the first SRO at a bottom of the first SRO to a first diameter and a first volume; patterning the solder resist layer and etching the solder resist layer to form a second SRO over the second bridge bump; and performing a second outline etch to remove a second portion of the solder resist layer at a bottom of the second SRO to a second diameter and a second volume that are less than the first diameter and the first volume.
Example embodiment 20: The method of embodiment 19, further comprising connecting logic die to the first bridge bump and the second bridge bump.

What is claimed is:

1. A device, comprising:
a substrate comprising a plurality of build-up layers and a cavity;
a bridge die located within the cavity;
a plurality of cavity side bumps on one side of the bridge die; and
a plurality of interconnect pads with variable heights on one of the build-up layers of the substrate, the plurality of interconnect pads coupled to the plurality of the cavity side bumps to bond the bridge die to the substrate.

2. The device of claim 1, wherein the plurality of interconnect pads range in height from +−25−50%.

3. The device of claim 1, wherein the plurality of interconnect pads comprise plated copper.

4. The device of claim 1, wherein the bridge die further includes a through-silicon via (TSV).

5. The device of claim 1, further comprising:
a solder resist (SR) layer comprising a first layer interconnect (FLI) on one side of the substrate;
a plurality of bridge bumps in the FLI; and
a logic die connected to the substrate through the plurality of bridge bumps.

6. The device of claim 5, further comprising:
a plurality of solder resist opens (SROs) in the FLI, a portion of the plurality of SROs having variable volumes; and
a conductive material filling the plurality of SROs to create a plurality of bond pads, the plurality of SROs filled with a same volume of conductive material, and a portion of the plurality of bond pads has variable heights due to the SROs having variable volumes, and the plurality of bond pads are connected to the plurality of bridge bumps.

7. The device of claim 6, wherein the bridge dies further includes a through-silicon via (TSV) connected to the plurality of bridge bumps to connect the bridge die to the logic die.

8. A method for fabricating a device, comprising:
forming a substrate comprising a plurality of build-up layers;
depositing a first resist layer on top of the substrate and patterning the first resist layer to create exposed areas;
depositing a conductive material in the exposed areas of the first resist layer to create a first set of interconnect pads to a first height;
depositing a second resist layer over the first resist layer and patterning the second resist layer to expose the first set of interconnect pads; and
depositing the conductive material over the first set of interconnect pads in the exposed areas of the second resist layer to create a second set of interconnect pads to a second height greater than the first height of the first set of interconnect pads.

9. The method of claim 8 further comprising: forming the first set of interconnect pads and the second set of interconnect pads to a height from +−25−50% of each other.

10. A device, comprising:
a substrate comprising a plurality of build-up layers and a cavity;
a bridge die located within the cavity;
a solder resist (SR) layer comprising a first layer interconnect (FLI) on one side of the substrate;
a plurality of bridge bumps in the FLI;
a logic die connected to the substrate through the plurality of bridge bumps;
a plurality of solder resist opens (SROs) in the FLI, a portion of the plurality of SROs having variable volumes; and
conductive material filling the plurality of SROs to create a plurality of bond pads, the plurality of SROs filled with a same volume of conductive material, and a portion of the plurality of bond pads has variable heights due to the SROs having variable volumes, and the plurality of bond pads are connected to the plurality of bridge bumps.

11. The device of claim 10 wherein the portion of the plurality of SROs having variable volumes has variable diameters.

12. The device of claim 11 wherein the plurality of SROs has a cross-section with an outline etch line near a midsection of the SROs.

13. The device of claim 10 wherein the portion of the plurality of SROs has variably increased or decreased volumes, and the portion of the plurality of bond pads has variably reduced or increased heights, respectively.

14. The device of claim 10 wherein a cross-section of the SROs having variable volumes and diameter differences.

15. The device of claim 10, wherein the bridge die further includes a through-silicon via (TSV) connected to the plurality of bridge bumps that connect the bridge die to the logic die.

16. The device of claim 10 further comprising: a plurality of a plurality of cavity side bumps on one side of the bridge die.

17. The device of claim 16, further comprising: a plurality of interconnect pads with variable heights on one of the plurality of build-up layers of the substrate coupled to the plurality of the cavity side bumps to bond the bridge die to the substrate.

18. The device of claim 17, wherein the interconnect pads range in height from +−25−50%.

19. A method of fabricating a device, the method comprising:
forming a substrate comprising a plurality of build-up layers;
forming at least a first bridge bump and a second bridge bump with uniform heights on the substrate;
depositing a solder resist layer on the substrate and patterning the resist layer to create a first solder resist open (SRO) over the first bridge bump;
performing a first outline etch to remove a first portion of the solder resist layer around a diameter of the first SRO at a bottom of the first SRO to a first diameter and a first volume;
patterning the solder resist layer and etching the solder resist layer to form a second SRO over the second bridge bump; and
performing a second outline etch to remove a second portion of the solder resist layer at a bottom of the second SRO to a second diameter and a second volume that are less than the first diameter and the first volume.

20. The method of claim 19, further comprising connecting logic die to the first bridge bump and the second bridge bump.
